(19) United States
(12) Patent Application Publication
(10) Pub. No.: US 2012/0268873 A1
(43) Pub. Date: Oct. 25, 2012

(54) Electronic Device and Holding Device Mounted on the Same

(75) Inventors: Hitoshi Nakatani, Osaka (JP); Takeshi Mori, Osaka (JP); Yuichiro Tachibana, Osaka (JP); Shun Shimazaki, Osaka (JP); Akira Iwamoto, Osaka (JP); Hideo Nishimatsu, Osaka (JP)

(73) Assignee: PANASONIC CORPORATION, Osaka (JP)

(21) Appl. No.: 13/454,104

(22) Filed: Apr. 24, 2012

(30) Foreign Application Priority Data
Apr. 25, 2011 (JP) 2011-097361
Apr. 13, 2012 (JP) 2012-092289

(51) Int. Cl. H05K 5/02; H05K 7/00

(52) U.S. Cl. 361/679.01; 16/429

(57) ABSTRACT

Disposed on a principal plane of a case is a pair of support members each having one end portion rotatably supported. The other end portions of the support members are supported rotatably by projections included in the case. A pair of loose-insertion openings through which the support parts are loosely inserted is arranged on the one end portions of the pair of support members. A gripping member having a configuration embedding the support members via the pair of loose-insertion openings is included. In a gripping device and an information processing device including the gripping device, concaved portions are formed on the support members at positions intersecting the pair of loose-insertion openings and facing the other support member. This configuration allows smooth rotational moving of the gripping member with regard to the information processing device, and suppressing pinching of foreign debris between the pair of support members and the gripping member.

### BACKGROUND OF THE INVENTION

1. Field of the Invention

The present application relates to gripping devices furnished with handles that can be gripped by a user. Furthermore, the present application relates to electronic devices furnished with the gripping devices.

2. Description of the Background Art

Personal computers on which handles are mounted for improving the portability have been available to date. Japanese Laid-Open Patent Publication No. H06-314138 and Japanese Laid-Open Patent Publication No. H06-309065 disclose configurations in which main units and grip portions of handles are fastened together by support members.

FIG. 8 shows a configuration of a notebook personal computer furnished with a conventional handle. FIG. 9 is a plan view of chief components of the handle and vicinity on the notebook personal computer shown in FIG. 8. The notebook personal computer shown in FIG. 8 and FIG. 9 includes a first case 101 including a keyboard and information processing means, and a second case 102 including a liquid crystal display, which are rotatably supported on each other. FIG. 8 and FIG. 9 show a folded-up state where the second case 102 is in close opposing contact with the first case 101. In addition, a lateral surface of the first case 101 includes a handle 104 that can be gripped by a user with his or her hand. The handle 104 is supported at both ends in a longitudinal direction thereof on the first case 101 by support members 141 and 142.

In addition, as shown in FIG. 9, formed inside the handle 104 at each ends in the longitudinal direction thereof are cavities 104a and 104b that have approximately oval shapes. A protruding portion 141a formed on the arm 141 loosely fits into the cavity 104a; and a protruding portion 142a formed on the support member 142 loosely fits into the cavity 104b. Furthermore, the opposite end of the end having arranged thereon the protruding portion 141a of the support member 141 loosely fits into a protruding portion 101a formed on the first case 101. In addition, the opposite end of the end having arranged thereon the protruding portion 141b of the support member 142 loosely fits into a protruding portion 101b formed on the first case 101. The support member 141 is rotatably supported around the protruding portion 101a that acts as an axis. In addition, the support member 142 is rotatably supported around the protruding portion 101b, serving as a pivot.

When the handle 104 in the conventional notebook personal computer configured as described above is to be used, the handle 104 is pulled out from a stored position (not shown) in a direction indicated by arrow Y. As a result, as shown in FIG. 8 and FIG. 9, space through which a hand can be inserted is formed between the handle 104 and the first case 101, and thereby the handle 104 becomes grippable. When the handle 104 is moved in the direction indicated by arrow Y, the support member 141 rotates around the protruding portion 101a serving as a pivot, and the support member 142 rotates around the protruding portion 101b serving as a pivot. In addition, the protruding portion 141a moves in the illustrated leftward direction within the cavity 104a, and the protruding portion 141b moves in the illustrated rightward direction within the cavity 104b.

Next, when storing the handle 104 that has been pulled out as shown in FIG. 8, the handle 104 is moved in a direction indicated by arrow X. As a result of such movement, the support member 141 rotates around the protruding portion 101a serving as a pivot, and the support member 142 rotates around the protruding portion 101b serving as a pivot. Thus, the handle 104 can be moved to the stored position.

However, in the configuration as shown in FIG. 8 and FIG. 9, since the support members 141 and 142 are configured so as to be rotatable with respect to the handle 104, slots 104d and 104e (hereinafter, referred to as “loose-insertion openings”), through which the support members 141 and 142 move in and out, are formed in the edge surface of the handle 104 in the vicinity of the locations along the contour of the handle 104 where the support members 141 and 142 are attached. Thus, when storing the handle 104 in the direction indicated by arrow X from the pulled-out position shown in FIG. 8 and FIG. 9, or when carrying the notebook personal computer in a state where the handle 104 is gripped by a hand, the angles R101 and R102 rapidly change by the notebook personal computer being jiggled, etc., and foreign debris may become pinched and caught inside the loose-insertion opening 104d or 104e, causing a problem where the movement for storing the handle 104 cannot be conducted smoothly.

### SUMMARY OF THE INVENTION

An electronic device disclosed by the present application includes a case having built therein electrical components, and a gripping device arranged on one principal plane of the case. The gripping device includes a pair of support members each having one end portion thereof rotatably supported on the one principal plane of the case, and a gripping member rotatably supported on the other end portions of the support members. The support members include concaved portions on inner surfaces thereof facing the other support member, at intersection portions where the support members intersect the gripping member.

A gripping device disclosed in the present application is a gripping device disposed on one principal plane of a case, and includes: a pair of support members each having one end portion thereof rotatably supported on the one principal plane of the case; and a gripping member that is rotatably supported on the other end portions of the support member, and that includes, at both end portions of the gripping member, intersection portions where the gripping member intersects with the support members, and that has a configuration for embedding the support member via the intersection portions. The support members include concaved portions at positions intersecting the intersection portions and facing the other support member.

The disclosure of the present application allows pull-out and storing motions and transporting motion of a handle to be conducted smoothly.

### BRIEF DESCRIPTION OF THE DRAWINGS

FIG. 1 is a perspective view of a notebook personal computer;

FIG. 2 is a plan view of a first case according to a given embodiment;

FIG. 3 is a plan view of the first case according to a given embodiment;

FIG. 4 is a plan view of a first cover member according to Embodiment 1;

FIG. 5 is a plan view of a second cover member according to Embodiment 1;

FIG. 6 is an exploded perspective view of a handle and an arm;

FIG. 7A is a chief-component plan view for describing pull-out and storing motions of the handle;

FIG. 7B is a chief-component plan view for describing the pull-out and storing motions of the handle;

FIG. 7C is a chief-component plan view for describing the pull-out and storing motions of the handle;

FIG. 8 is a perspective view showing a configuration of a conventional notebook personal computer; and

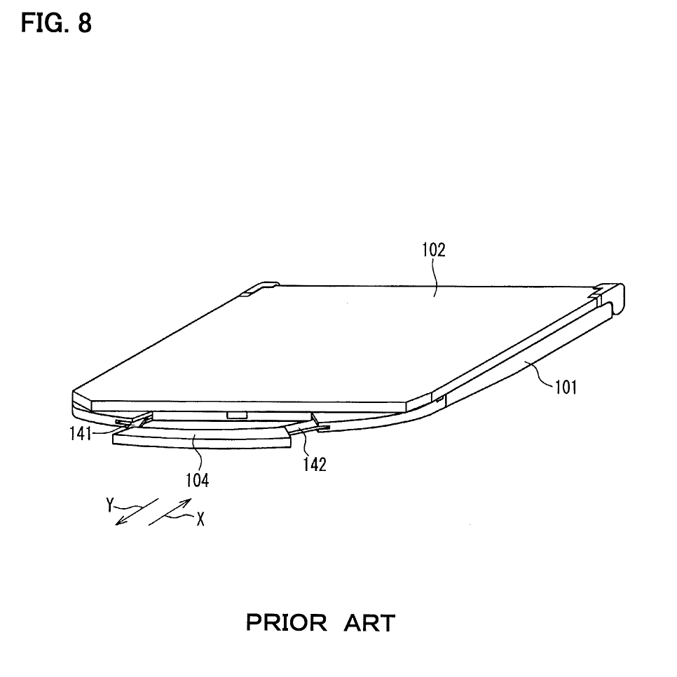

FIG. 9 is a plan view of a handle and vicinity in a conventional notebook personal computer.

### DESCRIPTION OF THE PREFERRED EMBODIMENTS

### Embodiments

### 1. Configuration of Electronic Device

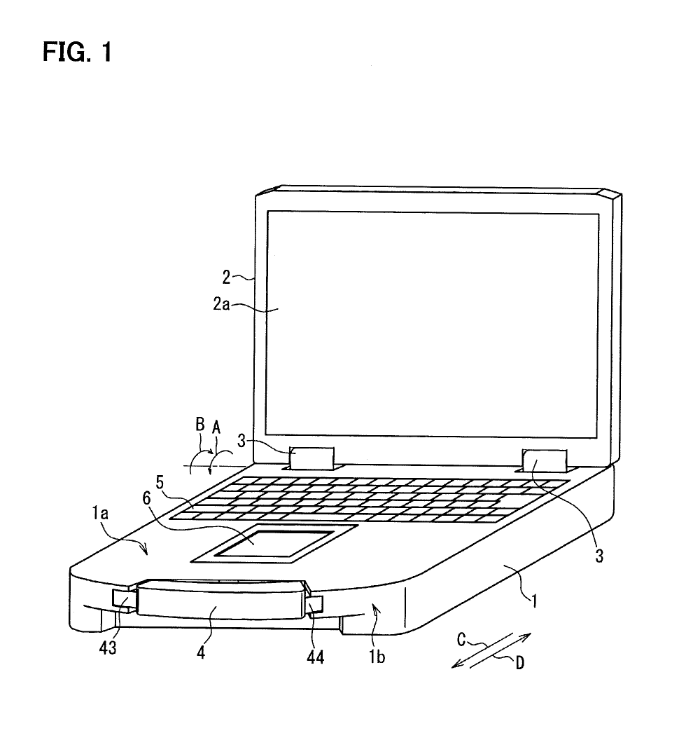

FIG. 1 is a perspective view showing an exterior of a notebook personal computer according to the present embodiment. The notebook personal computer shown in FIG. 1 is one example of an electronic device. In the present embodiment, although the notebook personal computer is used as one example of the electronic device, other instruments may be used as long as they include at least a handle that can be gripped by a user. Other than a notebook personal computer, the electronic device may be, for example, a tablet type personal computer or the like.

As shown in FIG. 1, the notebook personal computer includes a first case 1 and a second case 2. Components built in the first case 1 include a circuit board having mounted thereon various electric elements, and a storage device such as a hard disk drive. The second case 2 includes a display panel 2a. The display panel 2a can be achieved with, for example, a liquid crystal display panel. The first case 1 and the second case 2 are rotatably supported to each other through a hinge section 3. The hinge section 3 includes a rotation shaft that supports the first case 1 and the second case 2 rotatably in a direction indicated by arrow A or B. A keyboard 5 and a pointing device 6 are arranged on an upper surface la of the first case 1. A handle member 4 is arranged on a front surface lb of the first case 1.

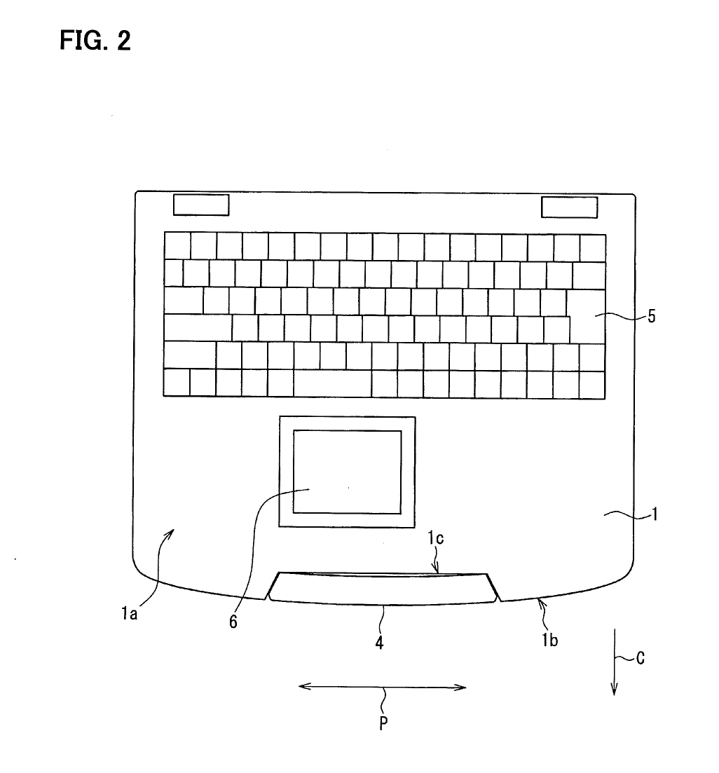

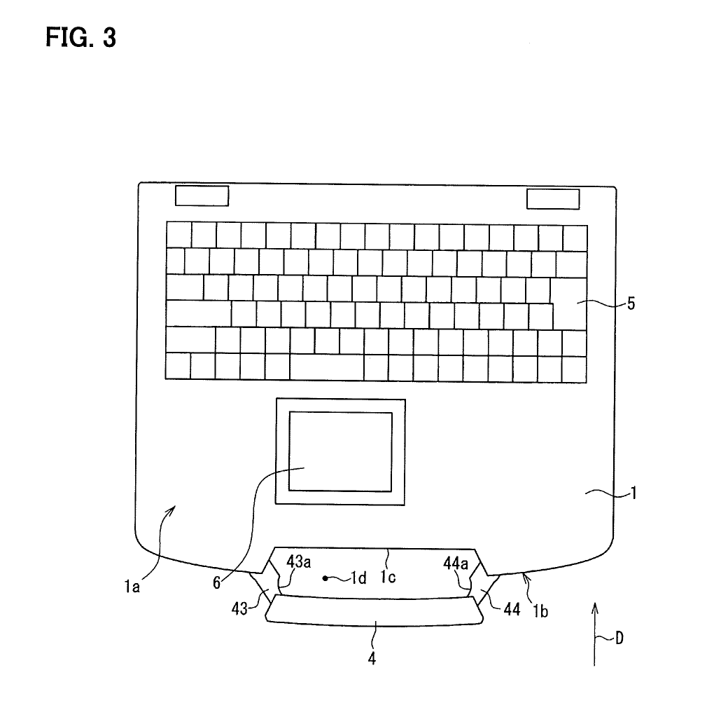

FIG. 2 and FIG. 3 are plan views of the first case 1. FIG. 2 shows a state where the handle member 4 is stored in a storage surface 1c of the first case 1. FIG. 3 shows a state where the handle member 4 is pulled out from the storage surface 1c of the first case 1. It should be noted that, the second case and the hinge section are omitted from FIG. 2 and FIG. 3 for simplification.

The handle member 4 is supported by the first case 1 through support members 43 and 44. The handle member 4 can be moved in a direction indicated by arrow C from a stored position shown in FIG. 1 and FIG. 2; and can also be moved in a direction indicated by arrow D from a position of being pulled out from the first case 1 shown in FIG. 3. As shown in FIG. 3, when the handle member 4 is in the pulled-out position of being pulled out, a gap portion 1d is formed at a position surrounded by the storage surface 1c of the first case 1, the handle member 4, the support member 43, and the support member 44. The gap portion 1d includes a spacing through which at least fingers of the user can be inserted when the user grips the handle member 4 with his or her hand.

### 2. Configuration and Motion of the Handle Member 4

The handle member 4 includes a first cover member 14 and a second cover member 15, and the two members are screwed together.

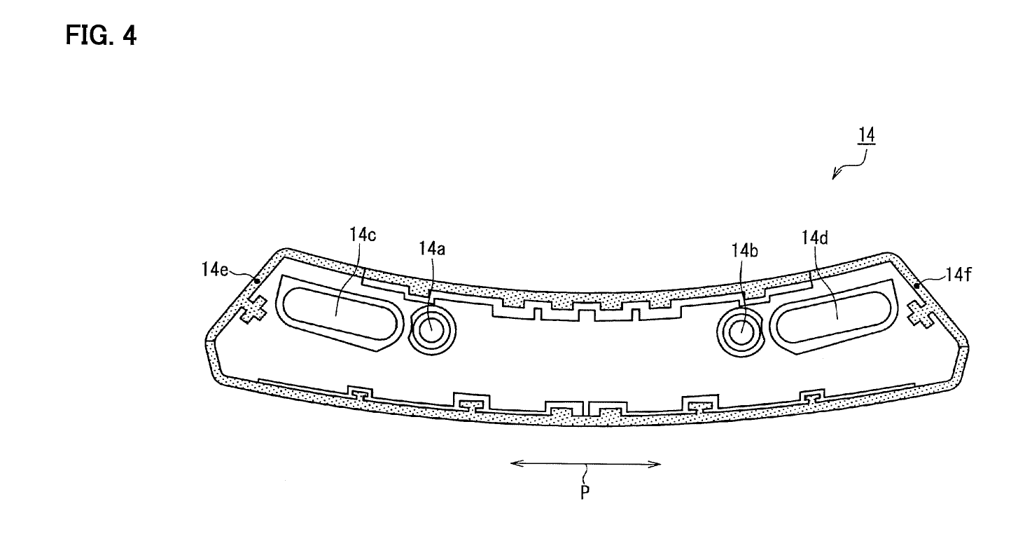

FIG. 4 is a plan view showing an inside configuration the first cover member 14 of the handle member 4 according to the present embodiment. The first cover member 14 includes hole sections 14a and 14b, and ellipse-shaped cavities 14c and 14d. The hole sections 14a and 14b have internal diameters that allow a screw (not shown) to be inserted therethrough. The hole sections 14a and 14b are formed so as to penetrate the first cover member 14. The basic shape of ellipse-shaped cavity 14c is a shape having a pair of straight lines and semicircular shapes connecting the pair of straight lines, as can be seen in, for example, a track used for tracks and fields. The ellipse-shaped cavity 14c engages a cylindrical protrusion (described later) formed at one end portion of the support member 44. The cylindrical protrusion (described later) engaging the ellipse-shaped cavity 14c can freely move in a longitudinal axis direction of the ellipse-shaped cavity 14c. The ellipse-shaped cavity 14d engages a cylindrical protrusion (described later) formed at one end portion of the support member 43. The cylindrical protrusion (described later) engaging the ellipse-shaped cavity 14d can freely move in a longitudinal axis direction of the ellipse-shaped cavity 14d. The first cover member 14 includes, on both ends in a longitudinal direction thereof, at end portions of the first cover member 14, openings 14e and 14f (hereinafter, referred to as “loose-insertion openings”) through which the support member 43 moves in and out. The loose-insertion opening 14e is a part through which the support member 43 is inserted. The loose-insertion opening 14f is a part through which the support member 44 is inserted. It should be noted that “the longitudinal direction of the first cover member 14” is, for example, a direction of a line segment connecting the center of the hole section 14a and the center of the hole section 14b, and is a direction of P axis shown in FIG. 4.

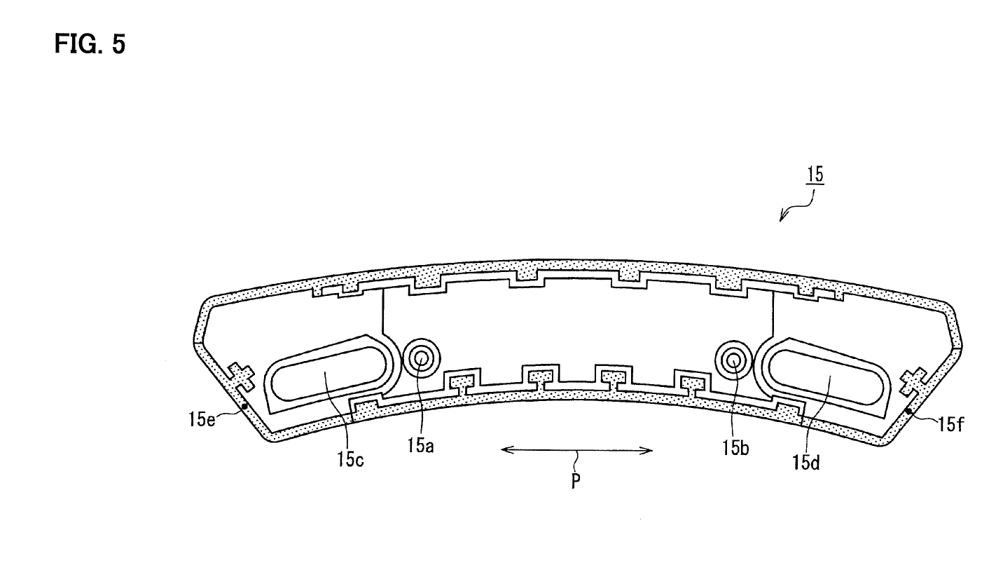

FIG. 5 is a plan view showing an inside configuration of the second cover member 15 of the handle member 4. The second cover member 15 includes screw holes 15a and 15b, and ellipse-shaped cavities 15c and 15d. The screw holes 15a and 15b have a female screw in which a screw (not shown) can be screwed. The ellipse-shaped cavity 15c engages the cylindrical protrusion (described later) formed at one end portion of the support member 43. The cylindrical protrusion (described later) engaging the ellipse-shaped cavity 15c can freely move in a longitudinal axis direction of the ellipse-shaped cavity 15c. Thus, the ellipse-shaped cavity 14c and the ellipse-shaped cavity 15c sandwich, in a freely movable manner in the longitudinal axis direction, the cylindrical protrusion (described later) formed at one end portion of the support member 44. The ellipse-shaped cavity 15d engages the cylindrical protrusion (described later) formed at the one end portion of the support member 44. The cylindrical protrusion (described later) engaging the ellipse-shaped cavity 15d can freely move in a longitudinal axis direction of the ellipse-shaped cavity 15d. Thus, the ellipse-shaped cavity 14d and the ellipse-shaped cavity 15d sandwich, in a freely movable manner in the longitudinal axis direction, the cylindrical protrusion (described later) formed at one end portion of the support member 44. The second cover member 15 includes, at both ends thereof in the longitudinal direction, loose-insertion openings 15e and 15f. The loose-insertion opening 15e is a part through which the support member 43 is inserted. The loose-insertion opening 15f is a part through which the support member 44 is inserted. It should be noted that “the longitudinal direction of the second cover member 15” is, for example, a direction of a line segment connecting the center of the screw hole 15a and the center of the screw hole 15b, and is a direction of P axis shown in FIG. 5.

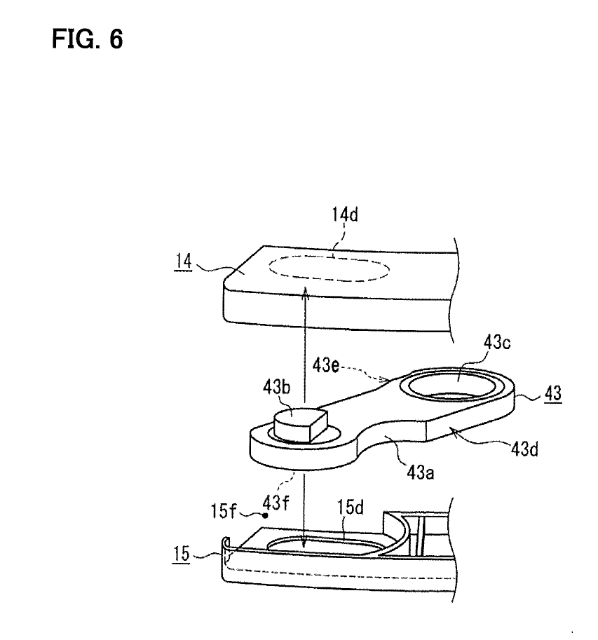

FIG. 6 is an exploded perspective view of the handle member 4. It should be noted that, although FIG. 6 shows a side on which the ellipse-shaped cavity 14d of the first cover member 14 of the handle member 4 is arranged, a side on which the ellipse-shaped cavity 14c is arranged has the same configuration. Furthermore, in the descriptions referring to FIG. 6, although description of only the support member 43 is provided, the support member 44 has a configuration symmetrical to the support member 43 with respect to a surface that vertically divides, into equal parts, the handle member 4 in the longitudinal direction, and description of it is omitted.

The support member 43 is preferably formed from a material having high strength such as a metal or the like so as to withstand stress caused when the user grips the handle member 4 for transporting the notebook personal computer and jiggles the notebook personal computer. As one example, in the present embodiment, the support member 43 is formed from magnesium. The support member 43 includes a concaved portion 43a, protruding portion 43b, a hole section 43c, a lateral surface 43d located on a side where the concaved portion 43a is formed, an opposite lateral surface 43e located on the opposite side with respect to the lateral surface 43d via the protruding portion 43b and the hole section 43c, and a protruding portion 43f located on the opposite side of the protruding portion 43b.

The concaved portion 43a has a curve-manner recessed shape. Thus, the concaved portion 43a, when installed on a notebook personal computer, has a curved shape cutout from an inner surface (in the drawings, the lateral surface 43d) of the support member 43 where the support member 43 and the support member 44 face each other, toward an external surface (in the drawings, the opposite lateral surface 43e). It should be noted that, as one example of a curve, the support members 43 and 44 are shown as having a circular arc shape. Furthermore, a vertex of the concaved portion 43a is a recessed part of the lateral surface 43d most proximal to the opposite lateral surface 43e. When the concaved portion 43a is assembled into the handle member 4, the concaved portion 43a is formed on the lateral surface 43d, which is located on a side where the concaved portion 43a of the support member 43 is formed. Furthermore, the lateral surface 43d of the support member 43 is one part of an inner circumference surface that forms the gap portion 1d when the support member 43 is coupled with the handle member 4 and the first case 1 as shown in FIG. 1 to FIG. 3. Thus, the concaved portion 43a is formed so as to be continuous to the gap portion 1d.

The protruding portion 43b is formed so as to project on both obverse and reverse side at the vicinity of one end portion of the support member 43 (in FIG. 6, only a protruding portion arranged on the obverse side of the support member 43 is diagrammatically represented). Although the protruding portion 43b is formed in an approximately half-cylinder shape, the shape is not limited thereto. The protruding portion 43b has an outer diameter that allows the ellipse-shaped cavity 14d of the first support member 14 to loosely fit therein. It should be noted that, the protruding portion 43f is arranged on the reverse side which is opposite of the obverse side of the support member 43 on which the protruding portion 43b is formed, in a mirroring relationship relative to the support member 43. The protruding portion 43f has an outer diameter that allows the ellipse-shaped cavity 15d of the second support member 15 to loosely fit therein.

The hole section 43c is a circular hole section formed in the vicinity of the other end portion of the support member 43. The hole section 43c has an internal diameter that allows an outer circumference cylindrical surface of a cylindrical projection 1e (described later) formed on the first case 1 to loosely fit therein.

It should be noted that, although diagrammatic representation with a perspective view as shown in FIG. 6 is omitted, similar to the support member 43, the support member 44 includes a concaved portion 44a, a protruding portion 44b, a hole section 44c, a lateral surface 44d located on a side where the concaved portion 44a is formed, an opposite lateral surface 44e located on the opposite side with respect to the lateral surface 44d via the protruding portion 44b and the hole section 44c, and a protruding portion 44f located on the opposite side of the protruding portion 44b. Furthermore, similar to the concaved portion 43a described above, the concaved portion 44a is formed on the lateral surface 44d, which is located on a side where the concaved portion 44a of the support member 44 is formed. The lateral surface 44d is one part of an inner circumference surface that forms the gap portion 1d. It should also be noted that, the protruding portion 44f is arranged on the reverse side which is opposite of the obverse side of the support member 44 on which the protruding portion 44b is formed, in a minoring relationship relative to the support member 44. The protruding portion 44f has an outer diameter that allows the ellipse-shaped cavity 15c of the second support member 15 to loosely fit therein. The support member 44 is formed from a metal such as magnesium.

In the above described configuration, the support members 43 and 44 are rotatably supported by the handle member 4 when the first cover member 14 and the second cover member 15 are joined such that the protruding portions 43b and 43f loosely fit the ellipse-shaped cavities 14d and 15d and such that the protruding portions 44b and 44f loosely fit the ellipse-shaped cavities 14c and 15c.

In this configuration, since the protruding portions 43b and 43f can move within the ellipse-shaped cavities 14d and 15d, the support member 43 can perform a rotational motion with respect to the handle member 4 using the protruding portions 43b and 43f as axes, and a motion of moving in the longitudinal axis direction of the ellipse-shaped cavities 14d and 15d. In addition, since the protruding portions 44b and 44f can move within the ellipse-shaped cavities 14c and 15c, the support member 44 can perform a rotational motion with respect to the handle member 4 using the protruding portions 44b and 44f as axes, and a motion of moving in the longitudinal axis direction of the ellipse-shaped cavities 14c and 15c.

In the following, the pull-out motion and the storing motion of the handle member 4 will be described.

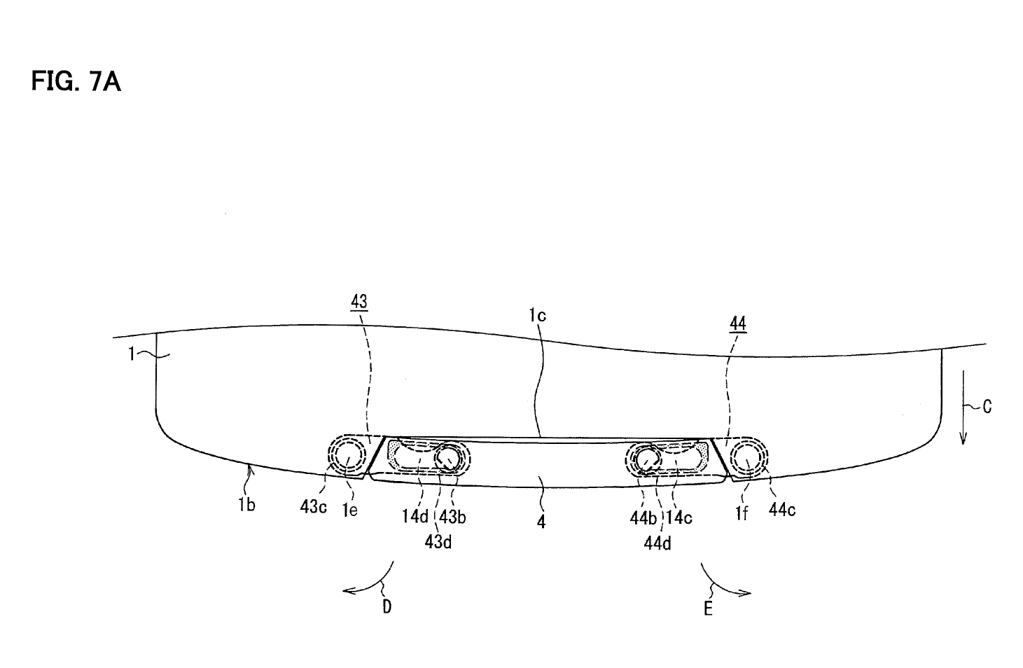

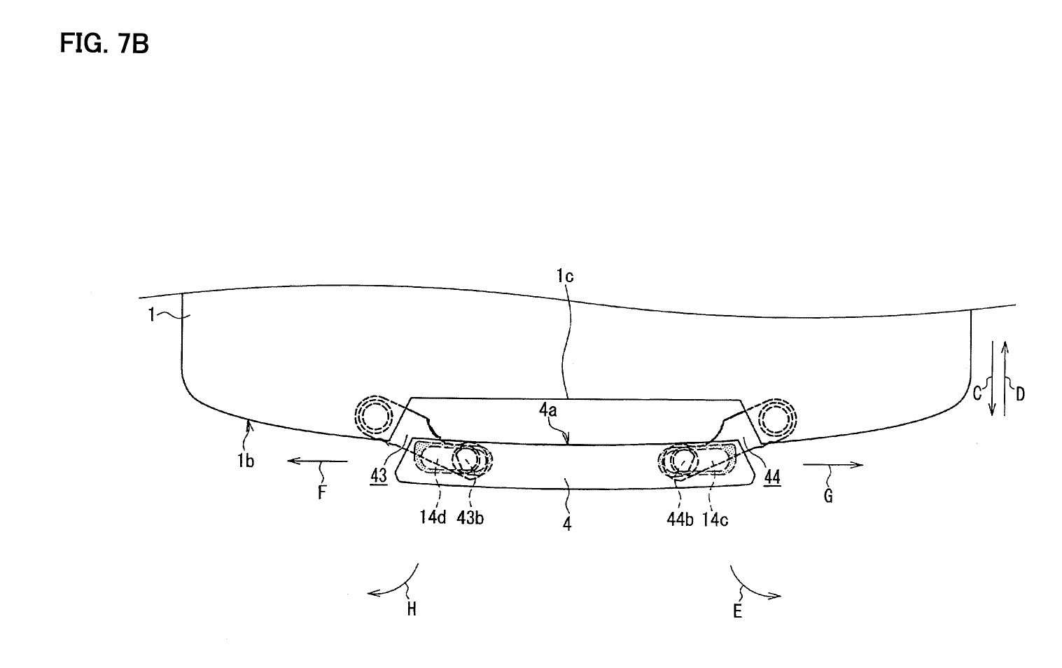

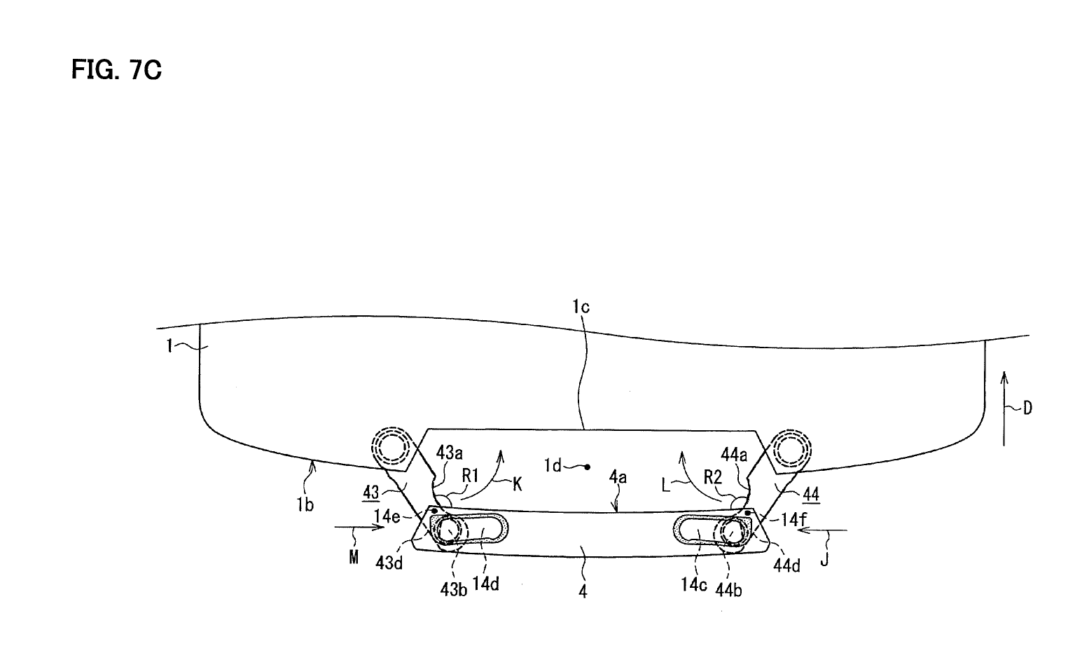

FIG. 7A is a chief-component plan view of the front surface lb of the first case 1 and vicinity when the handle member 4 is in the stored position. FIG. 7C is a chief-component plan view of the front surface lb of the first case 1 and vicinity when the handle member 4 is in the pulled-out position. FIG. 7B shows an intermediate state between FIG. 7A and FIG. 7C.

First, the pull-out motion for the handle member 4 will be described. As shown in FIG. 7A, when the handle member 4 is located at a position of being stored in the storage surface 1c of the first case 1, if the handle member 4 is pulled out in the direction indicated by arrow C, the handle member 4 moves in the direction indicated by arrow C while being supported by the support members 43 and 44. At this moment, as shown in FIG. 7B, the support member 43 rotates in a direction indicated by arrow H using the projection le included in the first case 1 as an axis, while the protruding portions 43b and 43f move in a direction indicated by arrow F in the longitudinal axis direction of the ellipse-shaped cavities 14d and 15d. In addition, as shown in FIG. 7B, the support member 44 rotates in a direction indicated by arrow E using a projection if included in the first case 1 as an axis, while the protruding portions 44b and 44f move in a direction indicated by arrow G in the longitudinal axis direction of the ellipse-shaped cavities 14c and 15c.

When the handle member 4 is further moved in the direction indicated by arrow C from the state shown in FIG. 7B, the handle member 4 moves until it reaches the pulled-out position shown in FIG. 7C, while being supported by the support members 43 and 44. In the pulled-out position shown in FIG. 7C, the protruding portions 43b and 44f are located at the end portions of the ellipse-shaped cavities 14d and 15d in the longitudinal axis direction. As a result, the support member 43 is restricted from rotating in the direction indicated by arrow H (FIG. 7B). In addition, in the pulled-out position as shown in FIG. 7C, the protruding portions 44b and 44f are located at the end portions of the ellipse-shaped cavities 14c and 15c in the longitudinal axis direction. As a result, the support member 44 is restricted from rotating in the direction indicated by arrow E (FIG. 7B). As a result of having the support members 43 and 44 restricted from rotating, the handle member 4 is restricted from moving in the direction indicated by arrow C (FIG. 7B).

Furthermore, when moving the handle member 4 from the pulled-out position shown in FIG. 7C to the stored position shown in FIG. 7A, the handle member 4 can be moved to the stored position shown in FIG. 7A through a reverse procedure movement of the above described pull-out motion.

### 3. Foreign Debris Pinching Prevention Function

In the present embodiment, the concaved portion 43a is formed on the support member 43, and the concaved portion 44a is formed on the support member 44. The concaved portion 43a is formed in a shape recessed as a curve in a direction from the lateral surface 43d toward the opposite lateral surface 43e (FIG. 6) at the end surface on the side of the loose-insertion openings 14f and 15f on a side of the surface where the support member 43 faces the gap portion 1d. Furthermore, the concaved portion 44a is formed in a shape recessed as a curve in a direction from the lateral surface 44d toward the opposite lateral surface 44e at the end surface on the side of the loose-insertion openings 14e and 15e on a side of the surface where the support member 44 faces the gap portion 1d. Formed position and dimensions (radius of curvature etc.,) of the concaved portion 43a are configured such that the concaved portion 43a intersects the loose-insertion openings 14e and 15e when the handle member 4 is located at the pulled-out position, the stored position, and an arbitrary position therebetween. Formed position and dimensions (radius of curvature etc.,) of the concaved portion 44a are configured such that the concaved portion 44a intersects the loose-insertion openings 14f and 15f when the handle member 4 is located at the pulled-out position, the stored position, and an arbitrary position therebetween. The formed position and the dimensions (radius of curvature etc.,) of the concaved portion 43a are configured such that the concaved portion 43a intersects the loose-insertion openings 14e and 15e no matter where the protruding portions 43b and 43f are located in the ellipse-shaped cavities 14d and 15d. The formed position and the dimensions (radius of curvature etc.,) of the concaved portion 44a are configured such that the concaved portion 44a intersects the loose-insertion openings 14f and 15f no matter where the protruding portions 44b and 44f are located in the ellipse-shaped cavities 14c and 15c. The concaved portions 43a and 44a are formed at positions facing the gap portion 1d.

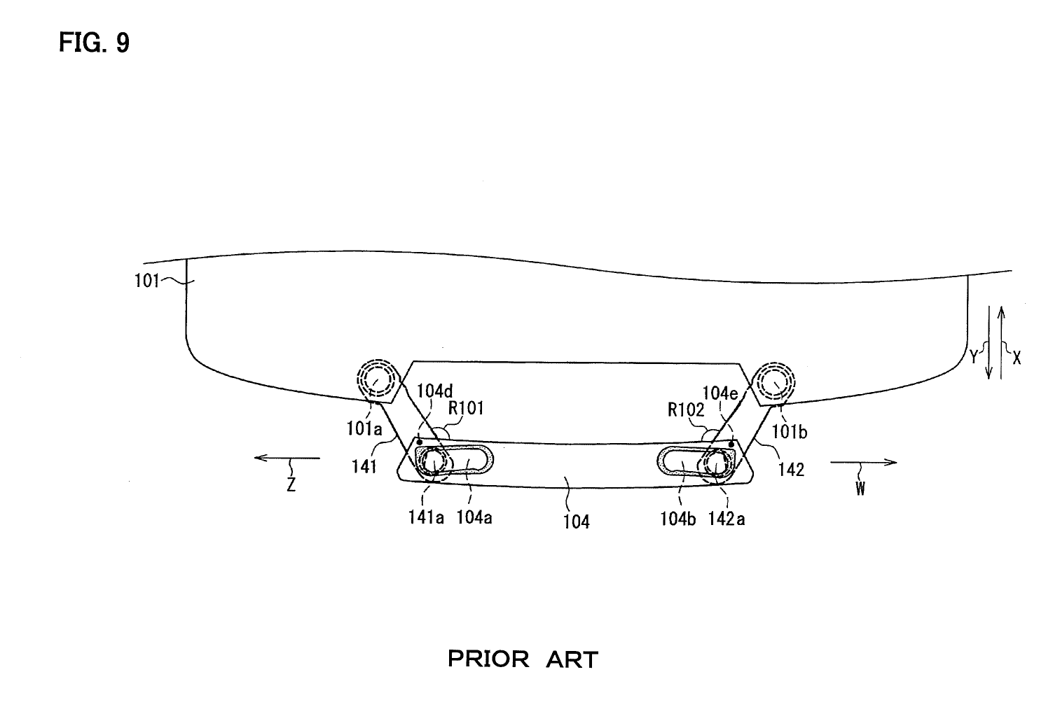

The handle member 4 includes a finger-side lateral surface 4a since, when the notebook personal computer is carried by hand, the fingers on the user's hand are inserted between the handle member 4 and the first case 1. The concaved portions 43a and 44a are formed such that angles R1 and R2 between the finger-side lateral surface 4a of the handle member 4 and the concaved portions 43a and 44a (an arbitrary tangent) are larger than angles R101 and R102 in the configuration (configuration that does not include the concaved portions 43a and 44a) shown in FIG. 9. The angles R1 and R2 may be any angle as long as foreign debris is unlikely to get caught between the finger-side lateral surface 4a of the handle member 4 and the concaved portions 43a and 44a when the support members 43 and 44 rotationally move with respect to the handle member 4. Thus, the inside angles between the finger-side lateral surface 4a, and the lateral surface 43d and the lateral surface 44d are obtuse angles. In other words, in a state where the handle member 4 is most separated from the storage surface 1c, the vertex of the concaved portion 43a of the support member 43 is located at an intersection portion between the support member 43 and the handle member 4 as shown in FIG. 7C. With this configuration, the support member 44 can move in and out the finger-side lateral surface 4a at the loose-insertion openings 14f and 15f as linearly as possible, and thereby foreign debris is unlikely to be pinched between the finger-side lateral surface 4a and the concaved portion 44a. In addition, since the concaved portion 43a of the support member 43 exposed on the finger-side lateral surface 4a has an inclination that monotonically changes from the vertex to the protruding portion 43b, the likelihood of pinching foreign debris during the process of storing the handle member 4 through the loose-insertion opening 43d can be reduced even when the protruding portion 43b moves within the ellipse-shaped cavity 14d. It should be noted that, the same operations and advantageous effects can be obtained even if the vertex is housed inside the handle member 4. Furthermore, the same applies for the support member 43 with regard to the loose-insertion openings 14e and 15e. The angle for these obtuse angles is preferably, for example, 140 to 180 degrees. It should be noted that the above described values (140 to 180 degrees) for the angles R1 and R2 are merely examples, and even when the angle is an angle that is not included within this range, the angle is within the scope of the present invention at least if foreign debris is not pinched between the finger-side lateral surface 4a of the handle member 4 and the concaved portions 43a and 44a. Furthermore, when the handle member 4 is to be moved in the direction of arrow C from the state shown in FIG. 7B, the movement is allowed in directions of arrows F and G; and when the handle member 4 is to be moved in the direction of arrow D, the movement is allowed in directions of arrows J and M. With this configuration, in accordance with the spacing between the handle member 4 and the storage surface 1c, changes occur in the location of the support member 43 at the loose-insertion openings 14e and 15e and the inside angle between the support member 43 and the opposite lateral surface 4a, and in the location of the support member 44 at the loose-insertion openings 14f and 15f and the inside angle between the support member 44 and the opposite lateral surface 4a. Therefore, the concaved portion 43a and the concaved portion 44a have contiguous curved surfaces with concaved shapes toward the opposite lateral surface 43e. Thus, the concaved portion 43a and the concaved portion 44a are exposed on the side of the storage surface 1c of the first case 1 between the stored position shown in FIG. 7A and the pulled-out position shown in FIG. 7C. It should be noted that, when a curved surface is formed on the finger-side lateral surface 4a facing the gap portion 1d in the handle member 4 so as to fit a user's palm, the angles R1 and R2 are preferably angles that are integrated to the curved surface of the handle member 4.

With the configuration described above, when the support members 43 and 44 rotationally move with regard to the handle member 4, chances of foreign debris being pinched between the handle member 4 and the support members 43 and 44 can be lessened. Specifically, as a result of the support member 43 including the concaved portion 43a and the support member 44 including the concaved portion 44a, changes in the angles R1 and R2 before the rotational motion and after the rotationally motion of the support members 43 and 44 become small, and thereby foreign debris is unlikely to be pinched between the handle member 4 and the support members 43 and 44. In order to reduce the changes in R1 and R2, the concaved portions 43a and 44a are preferably formed in circular arc shapes. In a state where the handle member 4 is pulled out, by forming the vertices of the circular arcs at the intersection portions where the handle member 4 intersects the support members 43 and 44 or by having the vertices stored in the handle member 4, the angles of R1 and R2 change gradually, and the angles can also be reduced, even when the handle member 4 is pulled out. For example, between the state shown in FIG. 7B and the state shown in FIG. 7C, although there is a large difference in the angles of the support members 43 and 44 with regard to the handle member 4, there is not a large difference in the angles R1 and R2 between the handle member 4 and the concaved portions 43a and 44a; and thereby foreign debris is unlikely to be pinched between the handle member 4 and the support members 43 and 44. Furthermore, for example, even if the handle member 4 is largely moved in a direction indicated by arrow J or M from the position shown in FIG. 7C, the angle R1 or R2 will not become extremely small (e.g., an acute angle), and thereby foreign debris is unlikely to be pinched between the handle member 4 and the support members 43 and 44.

On the other hand, with a configuration that does not include a concaved portion as shown in FIG. 9, when the support members 141 and 142 rotationally move, the angles R101 and R102 between the handle member 104 and the support members 141 and 142 largely change. In particular, when the handle member 104 is largely moved in a direction indicated by arrow W or Z, there are cases where an angle R101 or R102 becomes small (e.g., acute angle). Therefore, foreign debris can easily become pinched between the handle member 104 and the support members 141 and 142.

A situation where the support members 43 and 44 are rotationally moved with regard to the handle member 4 includes, for example, a case where the handle member 4 is moved from the stored position shown in FIG. 7A to the pulled-out position shown in FIG. 7C, and a case where, when the user is gripping the handle member 4 which is in the pulled-out position shown in FIG. 7C for transportation, the notebook personal computer is jiggled in a direction indicated by arrow J or M using the protruding portions 43b and 44b as axes.

### 4. Advantageous Effects of Embodiments, and Others

In the present embodiment, the support member 43 includes the concaved portion 43a, the support member 44 includes the concaved portion 44a, and the angles R1 and R2 between the finger-side lateral surface 4a of the handle member 4 and the concaved portions 43a and 44a have a large angle close to 180 degrees. As a result, it is possible to lessen the chances of foreign debris being pinched and caught between the finger-side lateral surface 4a of the handle member 4 and the support members 43 and 44 when the support members 43 and 44 rotationally move with regard to the handle member 4. Therefore, the handle member 4 can be moved smoothly.

It should be noted that, in the present embodiment, although the ellipse-shaped cavities 14c, 14d, 15c, and 15d are formed on the handle member 4; motion similar to the present embodiment can be achieved when ellipse-shaped cavities are formed at support positions of the support members 41 and 42 of the first case 1.

Furthermore, in the present embodiment, although the concaved portions 43a and 44a have recessed circular arc shapes, it is not essential to have the shapes to be circular arcs. For example, shapes recessed in polygonal shapes having multiple planes may be used.

Furthermore, in the present embodiment, although the support member 43 includes the concaved portion 43a and the support member 44 includes the concaved portion 44a; it is possible to have a concaved portion only on one of the support members.

Furthermore, in the present embodiment, although the support members 43 and 44 are fixed onto the first case 1, they may be fixed on the second case 2.

Furthermore, when the handle member 4 is in the stored position, the concaved portion 43a and the concaved portion 44a are preferably stored inside the handle member 4, or formed at the intersection portions between the handle member 4 and the support members 43 and 44. This is because, when the handle member 4 is stored, if the vertices of the concaved portions 43a and 44a are exposed outside, the support members 43 and 44 become exposed from the intersection portions via the vertices; and thereby there is a possibility that foreign debris become pinched due to changing of inclination directions of the handle member 4 and the surfaces of the concaved portions 43a and 44a at the intersection portions.

Furthermore, the handle member 4, the support member 43, and the support member 44 in the present embodiment are examples of gripping devices. The first case 1 according to the present embodiment is one example of a case. The handle member 4 according to the present embodiment is one example of a gripping member. The support members 43 and 44 according to the present embodiment are examples of support members. The loose-insertion openings 14e, 14f, 15e, and 15f according to the present embodiment are examples of intersection portions. The concaved portions 43a and 44a according to the present embodiment are examples of concaved portions.

What is claimed is:

1. An electronic device comprising:
a case having electrical components built therein; and
a gripping device disposed on one principal plane of the case, wherein the gripping device includes
a pair of support members each having one of opposing end portions thereof rotatably supported on the one principal plane of the case, and
a gripping member rotatably supported on the other of the opposing end portions of the support members, and
the support members are each formed with concaved portions on inner surfaces thereof facing the other support member, in the vicinity of intersection portions where the support members intersect the gripping member.

2. The electronic device according to claim 1, wherein:
the gripping member is reversibly shiftable between a stored position in proximity to the case, and a pulled-out position separated from the case; and
in the stored position, the concaved portions are housed inside the gripping member.

3. The electronic device according to claim 2, wherein:
the gripping member includes recesses whose outer peripheries have an elliptical shape;
the support member includes protruding portions that engage in the recesses; and
when the gripping member reversibly shifts between the stored position and the pulled-out position with respect to the case, the protruding portions move along the outer peripheries of the recesses.

4. The electronic device according to claim 1, wherein the concaved portions have shapes of circular arcs cutout from the inner surfaces, the circular arcs being arced toward an outer side of the support members.

5. The electronic device according to claim 1, wherein vertices of the inner surfaces most proximal to opposing outer sides of the support members are located either at said intersection portions or inside the gripping member when the gripping member is in a pulled-out position where the gripping member is most separated from the case.

6. A gripping device disposed on one principal plane of a case, the gripping device comprising:
a pair of support members each having one end portion thereof rotatably supported on the one principal plane of the case; and
a gripping member that is rotatably supported on the other end portions of the support members, and that includes, at both of end portions of the gripping member, intersection portions where the gripping member intersects with the support members, and that has a configuration for embedding the support member via the intersection portions; wherein
the support members include concaved portions at positions intersecting the intersection portions and facing the other support member.

7. The gripping device according to claim 6, wherein the gripping member is reversibly shiftable between a stored position in proximity to the case, and a pulled-out position separated from the case.

8. The gripping device according to claim 6, wherein:
the gripping member is reversibly shiftable between a stored position in proximity of the case, and a pulled-out position separated from the case; and
between the stored position and the pulled-out position, the concaved portions at the intersection portions are exposed toward a side of the case.
